(19) United States
(12) Patent Application Publication
(10) Pub. No.: US 2016/0279900 A1
(43) Pub. Date: Sep. 29, 2016

(54) ELECTROMAGNETIC-WAVE-ABSORBING HEAT DISSIPATION SHEET

(71) Applicants: JNC CORPORATION, Tokyo (JP); JNC PETROCHEMICAL CORPORATION, Tokyo (JP)

(72) Inventors: TAKESHI FUJIWARA, CHIBA (JP); YUKITO YADA, CHIBA (JP)

(73) Assignees: JNC CORPORATION, TOKYO (JP); JNC PETROCHEMICAL CORPORATION, TOKYO (JP)

(21) Appl. No.: 15/036,066

(22) PCT Filed: Nov. 12, 2014
(86) PCT No.: PCT/JP2014/079973

§ 371 Date: Jun. 16, 2016

(30) Foreign Application Priority Data
Nov. 14, 2013 (JP) 2013-236116

(51) Int. Cl. B32B 7/12; B32B 27/30; B32B 15/18; B32B 15/20; B32B 9/00; B32B 15/08

(52) U.S. Cl. CPC B32B 7/12; B32B 9/007; B32B 15/08; B32B 15/18; B32B 15/20; B32B 27/30; H01L 23/3735

(57) ABSTRACT

A problem is to provide an electromagnetic wave-absorbing and heat-dissipating sheet having high thermal conductivity and a complex function of absorbing electromagnetic waves, and to provide electronic equipment.

A solution is an electromagnetic wave-absorbing and heat-dissipating sheet, including at least one electromagnetic wave-absorbing layer including an electromagnetic wave absorbing material, at least one graphite layer formed of a graphite sheet, and at least one metal layer, wherein the graphite layer and other layers are adhered using an adhesive layer composed of a composition a containing polyvinyl acetal resin.

### TECHNICAL FIELD

The present invention relates to an electromagnetic wave-absorbing and heat-dissipating sheet that has a function of absorbing an electromagnetic wave noise while transferring heat from a heating unit such as a semiconductor, and electronic equipment using the same.

### BACKGROUND ART

In electronic equipment including a computer, and a heater element such as IGBT to be mounted in an electric vehicle, not only a heating value has increased in association with achieving high performance, but also high-frequency noise emission has become problematic. For example, a Central Processing Unit (CPU) mounted in a smart phone has a particularly large heating value, serves as a source of emitting both heat and an electromagnetic-wave (high-frequency) noise, and causes poor operation of the equipment.

Therefore, a large-sized heat sink and a shielding case are simultaneously used in a semiconductor device in many cases, which has problems of increasing a size of a casing or weight thereof. If highly thermally conductive graphite is used, weight reduction of the heat sink can be achieved. Specific examples of conventional technologies on a heat dissipater using such a kind of graphite include Patent literature No. 1.

As described above, the heating value has recently increased in the electronic equipment in association with achievement of high performance and high function, and therefore use of a thermal conductor having superb heat-dissipation characteristics has been required in the equipment. A method is disclosed in which a laminate prepared by causing adhesion of a graphite sheet and a metal sheet by an adhesive is used as such a thermal conductor (Patent literature Nos. 2 to No. 6).

The Patent literature No. 3 describes a method in which a rubber-like elastic adhesive or a silicone-based thermally conductive adhesive is used as an adhesive, the Patent literature No. 4 describes a method in which an adhesive containing an electrically conductive filler, such as silver, gold and copper is used, and the Patent literature No. 5 describes a method in which an acryl-based adhesive is used. The Patent literature No. 6 describes a laminate in which a polyvinyl acetal resin is used in an adhesion layer.

Patent literature No. 7 describes a method in which a composite of metal foil and a ferrite sheet is prepared and used in order to reduce the high-frequency noise.

### CITATION LIST

### Patent Literature

Patent literature No. 1: JP H11-21117 A

Patent literature No. 2: JP 2001-144237 A

Patent literature No. 3: JP H10-247708 A

Patent literature No. 4: JP 2004-23066 A

Patent literature No. 5: JP 2009-280433 A

Patent literature No. 6: JP 2008-53383 A

Patent literature No. 7: JP 2008-53383 A

### SUMMARY OF INVENTION

### Technical Problem

In the conventional thermal conductors (laminates) described in Patent literature Nos. 2 to 7, bond strength between a graphite sheet and a metal sheet has been insufficient in several cases.

Moreover, a layer composed of an adhesive (adhesive layer) ordinarily has a small thermal conductivity, and accordingly as the adhesive layer becomes thicker, thermal resistance in a lamination direction of the laminate becomes larger. A large thermal resistance of the adhesive layer has been unsolvable even if an electrically conductive adhesive layer is used, and such an electrically conductive adhesive layer has had weak bond strength. Therefore, use of an adhesive layer having excellent bond strength and having thickness as small as possible has been required.

However, the adhesive layers described in Patent literature Nos. 2 to 5 has low bond strength between the graphite sheet and the metal sheet. Therefore, a thermal conductor that can be used in the electronic equipment or the like has been unobtainable unless a thickness of the adhesive layer is increased in several cases. In the laminate having the thick adhesive layer, the weight has increased, and particularly the thermal resistance in the lamination direction of the laminate has been large, and the heat-dissipation characteristics have been poor in several cases. Further, depending on the adhesive layer (for example, the adhesive layer described in Patent literature No. 5) to be used, if a temperature of the laminate is raised by a difference of thermal expansion coefficients between the graphite sheet or the metal layer and the adhesive layer, the laminate has warped in several cases. Use of such a laminate in an electronic circuit or the like has caused a possibility in which the laminate and the electronic circuit are short-circuited, or graphite exposed on a surface by thermal shrinking or a physical shock is gradually peeled into electrically conductive powder to cause short-circuiting of the electronic circuit in several cases.

The laminate described in Patent literature No. 6 has excellent bond strength and heat-dissipation characteristics. However, a demand for electromagnetic wave (particularly high-frequency) noise absorption performance is still higher, and a solution of the problem has been required.

Moreover, the graphite sheet of Patent literature No. 7 for which the electromagnetic wave-absorbing function is provided has no self-standing performance, and formation of a three-dimensional structure for covering a semiconductor, such as a shielding case, has been difficult.

The invention has been made in view of such a problem, and an object thereof is to provide an electromagnetic wave-absorbing and heat-dissipating sheet that has lightweight and excellent electromagnetic wave-absorbing capability.

### Solution to Problem

The present inventors have diligently continued to conduct study in order to solve the problem, and as a result, have found that the problem can be solved by specific structure, namely forming a sheet having specific structure as a laminate of a graphite layer, a metal layer, and an electromagnetic wave-absorbing layer, and have completed the invention. More specifically, the invention includes the items described below.

Item 1. An electromagnetic wave-absorbing and heat-dissipating sheet, including at least one electromagnetic wave-absorbing layer including an electromagnetic wave-absorbing material, at least one graphite layer formed of a graphite sheet, and at least one metal layer, wherein the graphite layer and other layers are adhered using an adhesive layer composed of a composition containing a polyvinyl acetal resin.

Item 2. The electromagnetic wave-absorbing and heat-dissipating sheet according to item 1, wherein the electromagnetic wave-absorbing layer is a mixture of the electromagnetic wave-absorbing material and resin.

Item 3. The electromagnetic wave-absorbing and heat-dissipating sheet according to item 1 or 2, wherein the electromagnetic wave-absorbing material is a soft magnetic material or ferrite.

Item 4. The electromagnetic wave-absorbing and heat-dissipating sheet according to any one of items 1 to 3, wherein the electromagnetic wave-absorbing material is any one of kind selected from the group of Permalloy, Sendust, silicon steel, alloy Alperm, Permendur and electromagnetic stainless steel, or a mixture of two or more kinds thereof.

Item 5. The electromagnetic wave-absorbing and heat-dissipating sheet according to any one of items 1 to 4, wherein the metal layer includes copper, aluminum, magnesium or titanium.

Item 6. The electromagnetic wave-absorbing and heat-dissipating sheet according to anyone of items 1 to 5, wherein the polyvinyl acetal resin that forms the adhesive layer includes the following constitutional units A, B and C:

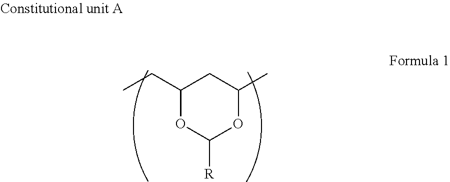

wherein, in constitutional unit A, R is independently hydrogen or alkyl:

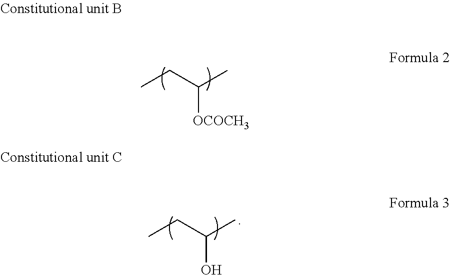

Item 7. The electromagnetic wave-absorbing and heat-dissipating sheet according to item 6, wherein the polyvinyl acetal resin further includes the following constitutional unit D:

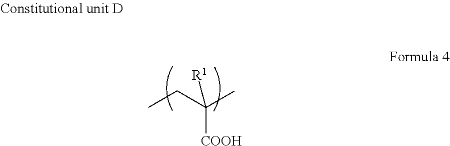

wherein, in constitutional unit D, R¹ is independently hydrogen or alkyl having 1 to 5 carbons.

Item 8. The electromagnetic wave-absorbing and heat-dissipating sheet according to anyone of items 1 to 7, wherein thermal conductivity of the graphite layer in a plane direction is 300 to 2,000 W/m·K.

Item 9. The electromagnetic wave-absorbing and heat-dissipating sheet according to any one of items 1 to 8, wherein a thickness of the adhesive layer is 5 micrometers or less.

Item 10. An electronic equipment, wherein the electromagnetic wave-absorbing and heat-dissipating sheet according to items 1 to 9 is brought into thermal contact with a heating unit.

### Advantageous Effects of Invention

The invention can provide an electromagnetic wave-absorbing and heat-dissipating sheet that has lightweight and an adhesive sheet having a small thickness, high bond strength between a metal layer and a graphite layer, excellent heat-dissipation performance and mechanical strength, and a capability of suppressing an electromagnetic wave noise. Further, the invention can provide electronic equipment or the like having excellent heat-dissipation performance, less malfunction and a capability of achieving weight reduction.

### BRIEF DESCRIPTION OF THE DRAWINGS

FIG. 1 is a cross-sectional schematic view showing one example of a heat-dissipating sheet prepared by laminating a metal layer and a graphite layer (Comparative Example 1).

FIG. 2 is a cross-sectional schematic view showing an electromagnetic wave-absorbing and heat-dissipating sheet in Example 1 of the invention.

FIG. 3 is a cross-sectional schematic view showing an electromagnetic wave-absorbing and heat-dissipating sheet in Comparative Example 2.

FIG. 4 is a cross-sectional schematic view showing an electromagnetic-wave absorbing and heat-dissipating sheet in Example 2 of the invention.

FIG. 5 is a cross-sectional schematic view showing one example of an electromagnetic wave-absorbing and heat-dissipating sheet of the invention.

FIG. 6 shows results of an EMI test of the electromagnetic wave-absorbing and heat-dissipating sheet of the invention (Example 1).

FIG. 7 shows results of an EMI test of a laminated sheet between copper and graphite, for which no noise suppression sheet is provided (Comparative Example 1).

FIG. 8 shows results of an EMI test of the electromagnetic wave-absorbing and heat-dissipating sheet of the invention (Example 2).

FIG. 9 shows results of an EMI test of the electromagnetic wave-absorbing and heat-dissipating sheet of the invention (Example 3).

### DESCRIPTION OF EMBODIMENTS

An electromagnetic wave-absorbing and heat-dissipating sheet of the invention is constituted of a heat-dissipating section having a role of diffusing heat from a heating unit in a plane direction, and an electromagnetic wave-absorbing layer that absorbs electromagnetic waves. The heat-dissipating section is a laminate in which at least one metal layer and at least one graphite layer are laminated through an adhesive layer formed by using a composition containing a polyvinyl acetal resin.

An order of laminating each layer that constitutes the electromagnetic wave-absorbing and heat-dissipating sheet of the invention only needs to be appropriately selected by taking into account desired heat-dissipation characteristics, corrosion resistance and so forth according to a desired application. The number of layers to be laminated also only needs to be appropriately selected in taking into account suppression of electromagnetic wave absorption and so forth according to the desired application.

A thickness of the laminate that constitutes the heat-dissipating section only needs to be appropriately selected in taking into account heat-dissipation performance of the heat-dissipating section, a size, weight and so forth required for the electronic equipment. The thickness is ordinarily 0.01 to 0.5 millimeter, and preferably 0.02 to 0.2 millimeter, but as long as desired advantageous effects of the invention are obtained, the thickness is not necessarily limited to the range.

The heat-dissipating section may be directly in contact with the heating unit, or may be in contact with the heating unit through a conventionally known layer such as a pressure-sensitive adhesive layer. As the conventionally known layer such as the pressure-sensitive adhesive layer, a layer that can adhere the heating unit with the heat-dissipating section in such a manner that the heating unit and the heat-dissipating section are integrated is preferred, and a layer that can efficiently transfer the heat from the heating unit to the heat-dissipating section is further preferred. Moreover, the heat-dissipating section may be arranged so as to be in contact with the heating unit by a method such as lapped flat seam or fastening with a clip.

### Heating Unit

The heating unit is not particularly restricted, and specific examples include an electronic device (specifically an IC (integrated circuit), a resistor and a capacitor), a battery, a liquid crystal display, a light-emitting element (an LED element and a laser light-emitting element), a motor and a sensor.

Hereinafter, each layer that constitutes the electromagnetic wave-absorbing and heat-dissipating sheet is described.

### 1. Adhesive Layer

The adhesive layer is not particularly restricted, as long as the layer is formed of the composition containing the polyvinyl acetal resin. The composition (hereinafter, also referred to as “composition for adhesive layer formation”) may be a composition consisting of the polyvinyl acetal resin, or a composition further containing a thermally conductive filler, an additive and a solvent, in addition to the resin, according to a kind of the metal layer or the like, in the range in which the advantageous effects of the invention are not adversely affected.

The electromagnetic wave-absorbing and heat-dissipating sheet having excellent bond strength between the metal layer and the graphite layer, being bendable and having excellent toughness, flexibility, heat resistance and impact resistance can be obtained by using such an adhesive layer.

### 1-1. Polyvinyl Acetal Resin

The polyvinyl acetal resin is not particularly restricted, but a resin including constitutional units A, B and C described below is preferred in view of obtaining the adhesive layer having excellent toughness, heat resistance and impact resistance and excellent adhesion between the metal layer and the graphite layer even with a small thickness.

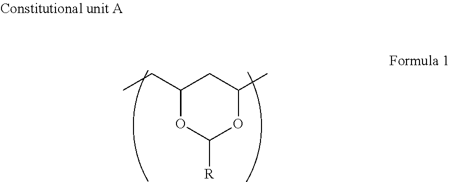

The constitutional unit A is a constitutional unit having an acetal moiety, and is formed, for example, by a reaction of a consecutive polyvinyl alcohol chain unit and aldehyde (R—CHO).

R in constitutional unit A is independently hydrogen or alkyl. If the R is a bulky group (for example, a hydrocarbon group having a large number of carbons), a softening point of the polyvinyl acetal resin tends to decrease. The polyvinyl acetal resin in which the R is the bulky group has a high solubility in a solvent, but has poor chemical resistance, on the other hand. Therefore, the R is preferably hydrogen or alkyl having 1 to 5 carbons, further preferably hydrogen or alkyl having 1 to 3 carbons in view of the toughness of the adhesive layer obtained, still further preferably hydrogen or propyl, and particularly preferably hydrogen in view of the heat resistance, and so forth.

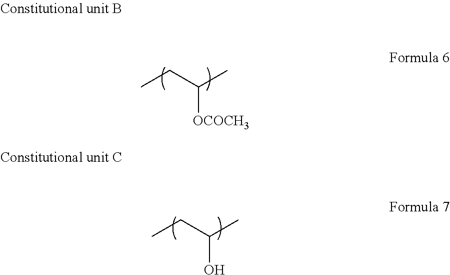

The polyvinyl acetal resin preferably includes constitutional unit D described below in addition to constitutional units A to C, in view of a capability of obtaining the adhesive layer having excellent bond strength with the metal layer or the graphite layer.

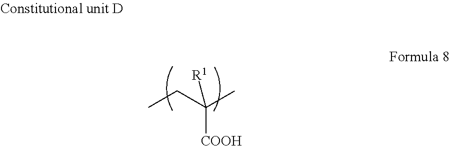

In the constitutional unit D, R¹ is independently hydrogen or alkyl having 1 to 5 carbons, preferably hydrogen or alkyl having 1 to 3 carbons, and further preferably hydrogen.

A total content of constitutional units A, B, C and D in the polyvinyl acetal resin is preferably 80 to 100 mol % based on total constitutional units in the resin.

Specific examples of other constitutional units that may be included in the polyvinyl acetal resin include a vinyl acetal chain unit other than constitutional unit A (constitutional unit in which R in the constitutional unit A is other than hydrogen or alkyl), an intermolecular acetal unit described below and a hemiacetal unit described below. A content of the vinyl acetal chain unit other than constitutional unit A is preferably less than 5 mol % based on the total constitutional units in the polyvinyl acetal resin.

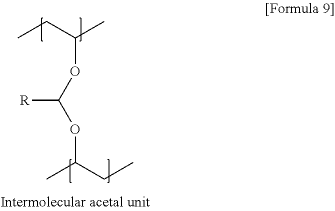

wherein, R in the intermolecular acetal unit is defined in a manner identical with the definition of R in the constitutional unit A.

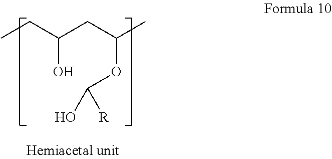

wherein, R in the hemiacetal unit is defined in a manner identical with the definition of R in the constitutional unit A.

In the polyvinyl acetal resin, constitutional units A to D may be arranged with regularity (a block copolymer, an alternate copolymer or the like) or may be arranged at random (a random copolymer), but preferably arranged at random.

In each constitutional unit in the polyvinyl acetal resin, a content of constitutional unit A is preferably 49.9 to 80 mol %, a content of constitutional unit B is preferably 0.1 to 49.9 mol %, a content of constitutional unit C is preferably 0.1 to 49.9 mol %, and a content of constitutional unit D is preferably 0 to 49.9 mol %, based on the total constitutional units in the resin. The content of constitutional unit A is further preferably 49.9 to 80 mol %, the content of constitutional unit B is further preferably 1 to 30 mol %, the content of constitutional unit C is further preferably 1 to 30 mol %, and the content of constitutional unit D is further preferably 0 to 30 mol %, based on the total constitutional units in the polyvinyl acetal resin.

In view of obtaining the polyvinyl acetal resin having excellent chemical resistance, flexibility, abrasion resistance and mechanical strength, the content of constitutional unit A is preferably 49.9 mol % or more.

If the content of the constitutional unit B is 0.1 mol % or more, solubility of the polyvinyl acetal resin in the solvent is improved, and therefore such a case is preferred. If the content of constitutional unit B is 49.9 mol % or less, chemical resistance, flexibility, abrasion resistance and mechanical strength of the polyvinyl acetal resin is hard to reduce, and therefore such a case is preferred.

In view of the solubility of the polyvinyl acetal resin in the solvent and adhesion performance of the obtained adhesive layer with the metal layer or the graphite layer, the content of constitutional unit C is preferably 49.9 mol % or less. Moreover, constitutional unit B and constitutional unit C are into an equilibrium relation upon acetalizing a polyvinyl alcohol chain in manufacture of the polyvinyl acetal resin, and therefore the content of constitutional unit C is preferably 0.1 mol % or more.

In view of a capability of obtaining the adhesive layer having excellent bond strength with the metal layer or the graphite layer, the content of constitutional unit D is preferably in the range described above.

The content of each of constitutional units A to C in the polyvinyl acetal resin can be measured in accordance with JIS K 6728 or JIS K 6729.

The content of constitutional unit D in the polyvinyl acetal resin can be measured by the method described below.

In a 1 mol/L sodium hydroxide aqueous solution, the polyvinyl acetal resin is warmed at 80° C. for 2 hours. Sodium is attached to a carboxyl group by the operation, and a polymer having —COONa is obtained. Excessive sodium hydroxide is extracted from the polymer, and then dehydration drying is performed. Then, the resulting material is carbonized, and subjected to atomic absorption spectrophotometry to perform quantitative determination in determining an amount of attached sodium.

In addition, upon analyzing the content of constitutional unit B (vinyl acetate chain), constitutional unit D is quantitatively determined as the vinyl acetate chain, and therefore the content of constitutional unit B is corrected by subtracting the content of quantitatively determined constitutional unit D from the content of constitutional unit B measured in accordance with JIS K 6728 or JIS K6729 as described above.

A weight average molecular weight of the polyvinyl acetal resin is preferably 5,000 to 300,000, and further preferably 10,000 to 150,000. If the polyvinyl acetal resin having the weight average molecular weight in the range described above is used, the electromagnetic wave-absorbing and heat-dissipating sheet can be easily manufactured, and the heat-dissipating section and a heat sink each having excellent molding processability or flexural strength are obtained, and therefore such a case is preferred.

The weight average molecular weight of the polyvinyl acetal resin only needs to be appropriately selected according to a desired purpose, but further preferably 10,000 to 40,000 in view of a capability of keeping a low temperature upon manufacturing the electromagnetic wave-absorbing and heat-dissipating sheet and obtaining the adhesive layer having high thermal conductivity, still further preferably 50,000 to 150,000 in view of a capability of obtaining the adhesive layer having high heat-resistant temperature.

In the invention, the weight average molecular weight of the polyvinyl acetal resin can be measured by gel permeation chromatography (GPC). Specific measurement conditions are as described below.

Detector: 830-RI (made by JASCO Corporation).

Oven: NFL-700M made by Nishio Kagu Industrial Art Co., Ltd.

Separation column: Shodex KF-805L×2.

Pump: PU-980 (made by JASCO Corporation).

Temperature: 30° C.

Career: tetrahydrofuran.

Standard sample: polystyrene.

Ostwald viscosity of the polyvinyl acetal resin is preferably 1 to 100 mPa·s. If the polyvinyl acetal resin having the Ostwald viscosity in the range described above is used, the electromagnetic wave-absorbing and heat-dissipating sheet can be easily manufactured, and the electromagnetic wave-absorbing and heat-dissipating sheet having excellent toughness is obtained, and therefore such a case is preferred.

The Ostwald viscosity can be measured using a solution prepared by dissolving 5 g of polyvinyl acetal resin in 100 mL of dichloroethane and using Ostwald-Cannon Fenske Viscometer at 20° C.

Specific examples of the polyvinyl acetal resin include polyvinyl butyral, polyvinyl formal, polyvinyl acetoacetal and a derivative thereof, and in view of the adhesion performance with the graphite layer and heat resistance of the adhesive layer, polyvinyl formal is preferred. The polyvinyl acetal resin may be used alone, or in combination of two or more kinds of resins being different in a sequence of bonding of structural units, the number of bonding or the like.

The polyvinyl acetal resin may be obtained by synthesis, or a commercially available product.

A method of synthesizing the resin including the constitutional units A, B and C is not particularly restricted, and specific examples include a method described in JP 2009-298833 A. A method of synthesizing the resin including the constitutional units A, B, C and D is not particularly restricted, and specific examples include a method described in JP 2010-202862 A.

Specific examples of the commercially available product of the polyvinyl acetal resin include Vinylec C and Vinylec K (made by JNC Corporation) as polyvinyl formal, and Denka Butyral 3000-K (made by Denka Co., Ltd.) as polyvinyl butyral.

### 1-2. Thermally Conductive Filler

When the adhesive layer includes the thermally conductive filler, thermal conductivity of the adhesive layer is improved, and particularly, the thermal conductivity in a lamination direction of the laminate is improved.

The electromagnetic wave-absorbing and heat-dissipating sheet having a thin adhesive layer, excellent heat-dissipation characteristics and processability, high bond strength with the metal layer or the graphite layer and excellent “bending” processability can be provided by using the adhesive layer including the thermally conductive filler. Moreover, such a product can be provided as the electronic device in which heat emitted from the heating unit is sufficiently removed and weight reduction and size reduction can be achieved, and the battery in which problems caused by heat generation are suppressed even at high energy density.

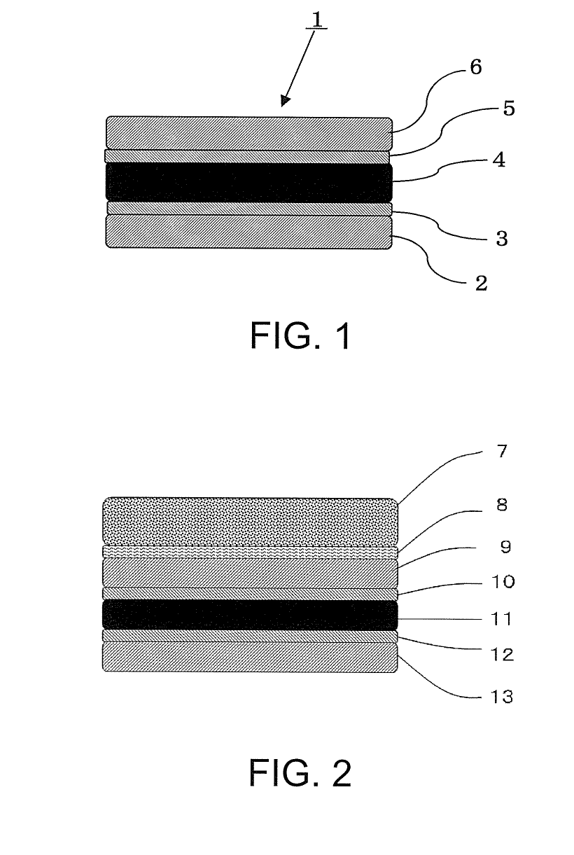

In the invention, “lamination direction of the laminate” means a longitudinal direction in FIG. 1, for example, more specifically, a thickness direction of the laminate.

The thermally conductive filler is not particularly restricted, and specific examples include a filler containing a metal or metal compound, such as metal powder, metal oxide powder, metal nitride powder, metal hydroxide powder, metal oxynitride powder and metal carbide powder, and a filler containing a carbon material.

Specific examples of the metal powder include powder composed of a metal such as gold, silver, copper, aluminum and nickel, and an alloy containing the metal thereof. Specific examples of the metal oxide powder include aluminum oxide powder, zinc oxide powder, magnesium oxide powder, silicon oxide powder and silicate powder. Specific examples of the metal nitride powder include aluminum nitride powder, boron nitride powder and silicon nitride powder. Specific examples of the metal hydroxide powder include aluminum hydroxide powder and magnesium hydroxide powder. Specific examples of the metal oxynitride powder include aluminum oxynitride powder, and specific examples of the metal carbide powder include silicon carbide powder and tungsten carbide powder.

Above all, in view of the thermal conductivity, ease of availability, and so forth, aluminum nitride powder, aluminum oxide powder, zinc oxide powder, magnesium oxide powder, silicon carbide powder and tungsten carbide powder are preferred.

In addition, when the filler containing the metal or metal compound is used as the thermally conductive filler, a filler containing a metal of a kind same as the kind of the metal that constitutes the metal layer is preferably used. If a filler containing a metal or metal compound different from the metal that constitutes the metal layer is used as the thermally conductive filler, a local cell is formed between the metal layer and the filler, and the metal layer or the filler is corroded in several cases.

A shape of the filler containing the metal or metal compound is not particularly restricted, and specific examples include a particle shape (including a spherical shape and an oval shape), a flat shape, a column shape, a needle-like shape (including a tetrapod-like and a dendritic shape) and an indefinite shape. Such shapes can be confirmed using a laser diffraction/dispersion particle size distribution measuring apparatus, or a scanning electron microscope (SEM).

As the filler containing the metal or metal compound, aluminum nitride powder, aluminum oxide powder, and needle-like (particularly tetrapod-like) zinc oxide powder are preferably used. Zinc oxide has a lower thermal conductivity in comparison with aluminum nitride, but if the tetrapod-like zinc oxide powder is used, the electromagnetic wave-absorbing and heat-dissipating sheet having superior heat-dissipation characteristics when the particle-shaped zinc oxide powder is used is obtained. Moreover, occurrence of peeling between the metal layer and the graphite layer can be reduced according to an anchor effect by using the tetrapod-shaped zinc oxide powder.

Moreover, aluminum oxide has a lower thermal conductivity in comparison with aluminum nitride or zinc oxide, but is chemically stable and neither reacts with water or an acid, nor dissolves in water or acid. Therefore, the electromagnetic wave-absorbing and heat-dissipating sheet having high weather resistance can be obtained. If aluminum nitride powder is used as the filler containing the metal or metal compound, the electromagnetic wave-absorbing and heat-dissipating sheet having superior heat-dissipation characteristics can be obtained.

A mean diameter of primary particles of the filler containing the metal or metal compound only needs to be appropriately selected according to a size of the electromagnetic wave-absorbing and heat-dissipating sheet to be desirably formed, a thickness of the adhesive layer or the like, but is preferably 0.001 to 30 micrometers and further preferably 0.01 to 20 micrometers in view of thermal conductivity of the adhesive layer in the lamination direction of the laminate, and so forth. The mean particle diameter of the filler containing the metal or metal compound can be confirmed using the laser diffraction/dispersion particle size distribution measuring apparatus or the scanning electron microscope (SEM).

In addition, the mean particle diameter of the filler containing the metal or metal compound means a diameter (length of a major axis in the case of the oval shape) of particles when the filler has the particle shape, a longest side when the filler has the flat shape, a longer side either a diameter of a circle (major axis of an ellipse) or a length of a column when the filler has the column shape, and a length of a needle when the filler has the needle-like shape.

Specific examples of the filler containing the carbon material include graphite powder (natural graphite, artificial graphite, expanded graphite, Ketjenblack), carbon nanotubes, diamond powder, carbon fibers, and fullerene, and above all, graphite powder, carbon nanotubes and diamond powder are preferred in view of excellent thermal conductivity, and so forth.

A mean diameter of primary particles of the filler containing the carbon material only needs to be appropriately selected according to a size of the electromagnetic wave-absorbing and heat-dissipating sheet to be desirably formed or the thickness of the adhesive layer or the like, but is preferably 0.001 to 20 micrometers and further preferably 0.002 to 10 micrometers in view of thermal conductivity of the adhesive layer in the lamination direction of the laminate, and so forth. The mean diameter of the filler composed of the carbon material can be confirmed using the laser diffraction/dispersion particle size distribution measuring apparatus, or the scanning electron microscope (SEM). In addition, the mean diameter of the carbon nanotubes or carbon fibers is represented by a length of the tubes or fibers.

As the thermally conductive filler, a commercially available product in which the mean diameter and the shape are in a desired range may be directly used, or a product obtained by grinding, classifying, or heating the commercially available product in such a manner that the mean diameter and the shape satisfy the desired range. In addition, the mean diameter or the shape of the thermally conductive filler varies in a process of manufacturing the electromagnetic wave-absorbing and heat-dissipating sheet in several cases. However, any filler is preferred if the filler has the mean diameter and the shape through such a process, and the mean diameter and the shape cause no problem unless the advantageous effects of the invention are adversely affected.

As the thermally conductive filler, a commercially available product subjected to surface treatment such as dispersion treatment or water-proof treatment may be directly used, and a product obtained by removing a surface treatment agent from the commercially available product may also be used. Moreover, a commercially available product subjected to no surface treatment may be surface-treated and used. In particular, aluminum nitride and magnesium oxide are easily deteriorated by moisture in air, and therefore a product subjected to the waterproof treatment is desirably used.

As the thermally conductive filler, the filler described above may be used alone, or in combination of two or more kinds thereof.

An amount of compounding the thermally conductive filler is preferably 1 to 80% by volume, further preferably 2 to 40% by volume, and sill further preferably 2 to 30% by volume, based on 100% by volume of the adhesive layer. If the thermally conductive filler is contained in the adhesive layer in the amount described above, the thermal conductivity of the adhesive layer is improved while the adhesion performance is maintained, and therefore such a case is preferred. If the amount of compounding the thermally conductive filler is in an upper limit or less of the range described above, the adhesive layer having high bond strength with the metal layer or the graphite layer is obtained, and if the amount of compounding the thermally conductive filler is in a lower limit or more of the range described above, the adhesive layer having high thermal conductivity is obtained, and therefore such a case is preferred.

### 1-3. Additive

The additive is not particularly restricted, as long as the advantageous effects of the invention are not adversely affected, and specific examples include an antioxidant, a silane coupling agent, a thermosetting resin such as an epoxy resin, a curing agent, a copper inhibitor, a metal deactivator, a corrosion inhibitor, a tackifier, an anti-aging agent, a defoaming agent, an antistatic agent, and a weather-resistant agent.

For example, when the resin forming the adhesive layer is deteriorated by contact with the metal, addition of the copper inhibitor or the metal deactivator described in JP H5-48265 A is preferred. In order to improve adhesion between the thermally conductive filler and the polyvinyl acetal resin, addition of the silane coupling agent is preferred, and in order to improve the heat resistance (glass transition temperature) of the adhesive layer, addition of the epoxy resin is preferred.

As the silane coupling agent, the silane coupling agents (trade names S330, S510, S520 and S530) made by JNC Corporation and so forth are preferred. An amount of addition of the silane coupling agent is preferably 1 to 10 parts by weight based on 100 parts by weight in the total amount of the resin included in the adhesive layer (A) in view of a capability of improving the adhesion between the adhesive layer and the metal layer.

The epoxy resin preferably includes jER828, jER827, jER806, jER807, jER4004P, jER152 and jER154 made by the Mitsubishi Chemical Corporation; Celloxide 2021P and Celloxide 3000 made by Daicel Corporation; YH-434 made by Nippon Steel & Sumikin Chemical Co., Ltd.; EPPN-201, EOCN-102S, EOCN-103S, EOCN-104S, EOCN-1020, EOCN-1025, EOCN-1027, DPPN-503, DPPN-502H, DPPN-501H, NC6000 and EPPN-202 made by Nippon Kayaku Co., Ltd.; DD-503 made by ADEKA Corporation; and Rikaresin W-100 made by New Japan Chemical Co., Ltd. An amount of addition of the epoxy resin is preferably 1 to 49% by weight based on 100% by weight in the total amount of the resin included in the adhesive layer in view of increasing the glass transition temperature of the adhesive layer, and so forth.

Upon adding the epoxy resin thereto, the curing agent is further preferably added thereto. The curing agent preferably includes an amine-based curing agent, a phenol-based curing agent, a phenol novolak-based curing agent and an imidazole-based curing agent.

The polyvinyl acetal resin composing the adhesive layer has been used for an enameled wire or the like for a long time, and is a resin that is hard to deteriorate by contact with the metal or hard to cause deterioration of the metal. However, when the electromagnetic wave-absorbing and heat-dissipating sheet is used under a high temperature and high humidity environment, the copper inhibitor or the metal deactivator may be added thereto. The copper inhibitor preferably includes Mark ZS-27 and Mark CDA-16 made by ADEKA Corporation; SANKO-EPOCLEAN made by Sanko Chemical Industry Co., Ltd.; and Irganox MD1024 made by BASF SE.

An amount of addition of the copper inhibitor is preferably 0.1 to 3 parts by weight based on 100 parts by weight in the total amount of the resin included in the adhesive layer in view of a capability of preventing deterioration of the resin in a part in contact with the metal in the adhesive layer.

### 1-4. Solvent

The solvent is not particularly restricted, as long as the solvent can dissolve the polyvinyl acetal resin, but is preferably a solvent capable of dispersing the thermally conductive filler. Specific examples include alcohol-based solvent such as methanol, ethanol, n-propanol, iso-propanol, n-butanol, sec-butanol, n-octanol, diacetone alcohol and benzyl alcohol; a cellosolve-based solvent such as methyl cellosolve, ethyl cellosolve and butyl cellosolve; a ketone-based solvent such as acetone, methyl ethyl ketone, cyclohexanone, cyclopentanone and isophorone; an amide-based solvent such as N,N-dimethylacetamide, N,N-dimethylformamide, and 1-methyl-2-pyrrolidone; an ester-based solvent such as methyl acetate and ethyl acetate; an ether-based solvent such as dioxane and tetrahydrofuran; a chlorinated hydrocarbon-based solvent such as dichloromethane, methylene chloride and chloroform; an aromatic solvent such as toluene and pyridine; dimethyl sulfoxide; acetic acid; terpineol; butyl carbitol; and butyl carbitol acetate. The solvents may be used alone, or in combination of two or more kinds thereof.

The solvent is preferably used to be preferably 3 to 30% by mass, and further preferably 5 to 20% by mass in a resin concentration in the composition for adhesive layer formation in view of the ease of manufacture, the heat-dissipation characteristics of the electromagnetic wave-absorbing and heat-dissipating sheet, and so forth.

A thickness of the adhesive layer is not particularly restricted, and is preferably as small as possible as long as the adhesive layer has the thickness at which the adhesive layer can adhere the metal layer with the graphite layer in view of a capability of reducing thermal resistance and so forth. The thickness is further preferably 30 micrometers or less, and still further preferably 10 micrometers or less, and particularly preferably 7 micrometers or less. In the electromagnetic wave-absorbing and heat-dissipating sheet, the adhesive layer is formed by using the composition containing the polyvinyl acetal resin, and therefore even if the thickness of the adhesive layer is 1 micrometer or less, the adhesive layer can adhere the metal layer with the graphite layer.

In addition, the thickness of the adhesive layer means a thickness between the metal layer or the graphite layer in contact with one plane of one layer of the adhesive layer, and the metal layer or the graphite layer in contact with a plane opposite to the plane of the adhesive layer, the plane with which the metal layer or the graphite layer is in contact. Moreover, the thermally conductive filler that may be included in the adhesive layer is stuck into the graphite layer in several cases. However, even in such a case, the thickness of the adhesive layer means the thickness between the metal layers and/or the graphite layers without considering a filler part stuck into the graphite layer.

### 2. Metal Layer

The metal layer is laminated for improvement in heat capacity, mechanical strength, processability of the heat-dissipating section, and so forth. The metal layer includes preferably a layer including a metal having excellent thermal conductivity, further preferably a layer including gold, silver, copper, aluminum, nickel and an alloy containing at least one kind thereof, still further preferably a layer including silver, copper, aluminum, nickel and an alloy containing at least one kind thereof, and particularly preferably a layer including at least one selected from the group of copper, aluminum and an alloy containing at least one kind thereof.

The alloy may be in any state of a solid solution, a eutectic alloy or an intermetallic compound. Specific examples of the alloy include phosphor bronze, copper nickel and duralumin.

A thickness of the metal layer is not particularly restricted, and only needs to be appropriately selected in taking into account an application, weight, thermal conductivity and so forth of the electromagnetic wave-absorbing and heat-dissipating sheet to be obtained. However, the thickness is preferably 0.01 to 100 times the thickness of the graphite layer, and further preferably 0.1 to 10 times the thickness thereof. If the thickness of the metal layer is in the range described above, the electromagnetic wave-absorbing and heat-dissipating sheet having excellent heat-dissipation characteristics and mechanical strength can be obtained.

### 3. Graphite Layer

The graphite layer has large thermal conductivity, and is lightweight and enriched in flexibility. The electromagnetic wave-absorbing and heat-dissipating sheet having excellent heat-dissipation characteristics and lightweight can be obtained by using such a graphite layer. The graphite layer is not particularly restricted, as long as the graphite layer is a layer composed of graphite. For example, the graphite layer manufactured by a method described in JP S61-275117 A and JP H11-21117 A may be used, or a commercially available product may also be used.

Specific examples of the commercially available product include, as an artificial graphite sheet manufactured of a synthetic resin sheet, eGRAF SPREADERSHIELD SS-1500 (made by GrafTECH International Holding Inc.), Graphinity (made by Kaneka Corporation), and PGS graphite sheet (made by Panasonic Corporation), and include, as a natural graphite sheet manufactured of natural graphite, eGRAF SPREADERSHIELD SS-500 (made by GrafTECH International Holding Inc.).

In the graphite layer, the thermal conductivity in a direction substantially perpendicular to the lamination direction of the laminate is preferably 250 to 2,000 W/m·K, and further preferably 500 to 2,000 W/m·K. When the thermal conductivity of the graphite layer is in the range described above, the electromagnetic wave-absorbing and heat-dissipating sheet having excellent heat-dissipation performance and thermal uniformity can be obtained. The thermal conductivity of the graphite layer in the direction substantially perpendicular to the lamination direction of the laminate can be measured by measuring thermal diffusivity, specific heat capacity and density by using a laser flash or xenon flash thermal diffusivity measuring apparatus, DSC and an Archimedes method, and multiplying values thereof.

A thickness of the graphite layer is not particularly restricted. In order to obtain the electromagnetic wave-absorbing and heat-dissipating sheet having excellent heat-dissipation characteristics, the graphite layer preferably has a moderate thickness. Specifically, the thickness is preferably 10 to 600 micrometers, further preferably 15 to 500 micrometers and particularly preferably 20 to 300 micrometers.

### 4. Electromagnetic Wave-Absorbing Layer

The electromagnetic wave-absorbing and heat-dissipating sheet of the invention preferably has an electromagnetic wave-absorbing resin layer on one plane or both planes of an outermost layer of the laminate if taking into account electromagnetic wave-absorbing characteristics. The electromagnetic wave-absorbing resin layer is composed of the composition containing a filler having electromagnetic wave-absorbing characteristics and resin.

### 4-1. Resin Forming Electromagnetic Wave-Absorbing Layer

The resin forming the electromagnetic wave-absorbing resin layer include a composition containing one kind or two or more kinds of resins that can uniformly disperse and mix the filler having electromagnetic wave-absorbing characteristics. The resin only needs to be an organic electric insulator such as rubber and resin, and specific examples include an acrylic resin, an epoxy resin, an alkyd resin, a urethane resin, polyimide, cellulose nitrate, polyvinyl acetal, silicone rubber, polyether and polyolefin, and among the resins, a heat-resistant resin is preferred. Moreover, the resin having high insulation performance is preferred.

### 4-2. Electromagnetic Wave-Absorbing Filler

Specific examples of the electromagnetic wave-absorbing filler include a conventionally known spinel ferrite material having a composition of MeFe₂O₄ (Me=NiZn, MnZn, NiZnCu or MgMn). A particle size of the electromagnetic wave-absorbing filler is preferably larger than 0.01 micrometer. In particular, the particle size is preferably 0.1 micrometer or more in view of avoiding excessively high viscosity upon kneading the sheet and a good sheet aspect.

Moreover, if the particle size of the electromagnetic wave-absorbing filler is smaller than 100 micrometers, no drop of particles (powder drop) is caused from the sheet and the sheet aspect is good.

An electromagnetic wave-absorbing material as the filler may also be, in addition to the ferrite material described above, a material being flaky powder composed of any one kind or a plurality of kinds of soft magnetic metals selected from pure Fe, a nickel-Fe alloy (Permalloy), an Fe—Al—Si alloy (Sendust), an Fe—Si alloy (silicon steel), an Fe—Al alloy (alloy Alperm), a Fe—Co alloy (Permendur), and electromagnetic stainless steel, in which flat powder having a particle size of 0.01 to 100 micrometers and an aspect ratio (diameter/thickness) of 5 to 100 is contained in the resin forming the electromagnetic wave-absorbing layer in a volume filling factor of 30 to 65 vol % to allow orientational dispersion, and a thickness is adjusted to an arbitrary value of 0.05 to 3 millimeters. The filler has a larger magnetic loss in comparison with ferrite powder, and therefore the electromagnetic wave-absorbing characteristics are improved. A metallic filler having high thermal conductivity contributes also to heat dissipation.

If the aspect ratio of the electromagnetic wave-absorbing filler is larger than 5, absorption frequency is suitable, and such a case is preferred. If the aspect ratio is smaller than 100, the absorption frequency shifts to a higher region, and therefore such a case is preferred. If the volume filling factor of the flat powder is larger than 30 vol %, absorption performance is good, and such a case is preferred. If the volume filling factor is smaller than 65 vol %, kneading is easy and no powder drop is caused, and such a case is preferred. The electromagnetic wave-absorbing layer can be formed by preliminarily kneading the electromagnetic wave-absorbing filler and the resin and then processing the kneaded material into a sheet form, and laminating the material with the heat-dissipating section. On the above occasion, if a sheet thickness is larger than 0.05 millimeter, such a case is preferred in view of achieving easy sheet formation and easy handling. If the sheet thickness is smaller than 3 millimeters, allowance is formed in a space on an equipment side, and such a case is preferred.

Accordingly, as a thickness of the electromagnetic wave-absorbing layer is larger, the electromagnetic wave-absorbing characteristics are improved, but the layer has lower thermal conductivity in comparison with the graphite sheet, and therefore heat is easily confined therein. Thus, the thickness is preferably adjusted to about 0.01 millimeter to 2 millimeters.

### 5. Other Layers

The electromagnetic wave-absorbing sheet of the invention may include a layer other than the metal layer, the electromagnetic wave-absorbing layer, the adhesive layer and the graphite layer according to a desired application. For example, a resin layer may be provided for the purpose of preventing powder drop of the electromagnetic wave-absorbing filler from a ferrite layer. Further, a conventionally known film may be preferably pasted on an outermost plane for the purpose of securing insulation performance, and a film in taking into account the thermal conductivity is further preferred. When the electromagnetic wave-absorbing and heat-dissipating sheet is used under high temperature conditions, for example, a heat-resistant film such as a polyimide film is preferred as such a film. A thickness of the film is ordinarily selected from 5 to 200 micrometers at which handling is easy, preferably 10 micrometers or more, and 50 micrometers or less in view of a small thermal resistance value.

Specific examples of the layer other than the metal layer, the adhesive layer, the electromagnetic wave-absorbing layer and the graphite layer include a conventionally known layer having adhesion performance. Specific examples of the laminate having such a layer include a laminate in which a preformed film made of a resin composed of polyethylene terephthalate, polyimide, polyamide or vinyl chloride is laminated on one plane or both planes of a metal layer or a graphite layer being the outermost layer of the laminate through a commercially available pressure-sensitive adhesive sheet (layer having pressure-sensitive adhesion performance) composed of an acryl-based or silicone-based pressure-sensitive adhesive.

The resin layer may be formed directly on the electromagnetic wave-absorbing layer, or may be formed in the form of the heat-dissipating section. In any case, the resin layer may be adhered thereon through the commercially available pressure-sensitive adhesive sheet.

### 5. Method of Manufacturing Laminate

In the laminate, connection between metal and graphite is described in detail below.

The laminate can be manufactured by applying the composition for adhesive layer formation onto the metal sheet for forming the metal layer or the graphite sheet for forming the graphite layer, and when necessary, preliminarily drying the resulting material, and then arranging both the metal sheet and the graphite sheet so as to interpose the composition therebetween, and heating the resulting assembly while pressure is applied. Moreover, upon manufacturing the laminate, the composition for adhesive layer formation is preferably applied onto both of the metal sheet and the graphite sheet in view of obtaining the electromagnetic wave-absorbing and heat-dissipating sheet in which the bond strength between the metal layer and the graphite layer is high.

Before applying the composition for adhesive layer formation, with regard to the metal layer, an oxide layer on a surface thereof is preferably removed or the surface is preferably degreased and cleaned, and with regard to the graphite layer, a surface is preferably subjected to easy adhesion treatment by an oxygen plasma apparatus, strong acid treatment in view of obtaining the electromagnetic wave-absorbing and heat-dissipating sheet in which the bond strength between the metal layer and the graphite layer is high.

A method of applying the composition for adhesive layer formation onto the metal sheet or the graphite sheet is not particularly restricted, but a wet coating method by which the composition can be uniformly coated is preferred. Among the wet coating methods, a spin coating method that is simple and capable of forming a homogeneous film is preferred when a thin adhesive layer is formed. When productivity is emphasized, a gravure coating method, a die coating method, a bar coating method, a reverse coating method, a roll coating method, a slit coating method, a spray coating method, a kiss coating method, a reverse kiss coating method, an air knife coating method, a curtain coating method, a rod coating method or the like is preferred.

The preliminary drying is not particularly restricted and may be performed by leaving the resulting material for one to seven days at room temperature, but preferably performed by heating for about 1 minute to 10 minutes at a temperature of about 80 to 120° C. on a hot plate, in a drying furnace or the like. The preliminary drying only needs to be performed in air, but if desired, may be performed in an atmosphere of inert gas such as nitrogen and rare gas, or under reduced pressure. In particular, when the composition is dried in a short period of time at a high temperature, drying is preferably performed under an inert gas atmosphere.

The method of heating while the pressure is applied is not particularly restricted, but the pressure is preferably 0.1 to 30 MPa, the temperature is preferably 200 to 250° C., and a heating and pressurization time is preferably 1 minute to 1 hour. Moreover, the heating only needs to be performed in air, but if desired, may be performed under an atmosphere of inert gas such as nitrogen and rare gas, and may be performed under reduced pressure. In particular, when the composition is heated in a short period of time at a high temperature, heating is preferably performed under an inert gas atmosphere or under reduced pressure.

In view of an effect of electromagnetic wave absorption, the electromagnetic wave-absorbing and heat-dissipating sheet of the invention preferably has the electromagnetic wave-absorbing layer on one plane or both planes of the outermost layer. The electromagnetic wave-absorbing layer may be made by applying, as a coating material, the electromagnetic wave-absorbing composition containing an electromagnetic wave-absorbing resin and the electromagnetic wave-absorbing filler and composing the electromagnetic wave-absorbing composition onto one plane or both planes of the metal layer or the graphite layer that forms the outermost layer of the laminate, and when necessary drying the resulting coating, and curing the coating.

A method of applying the electromagnetic wave-absorbing composition as the coating material onto the heat-dissipating section is not particularly restricted, but the wet coating method that can uniformly coat the composition is preferred. When a thin adhesive layer is formed, the spin coating method that is simple and capable of forming the homogeneous film is preferred among the wet coating methods. When productivity is emphasized, the gravure coating method, the die coating method, the bar coating method, the reverse coating method, the roll coating method, the slit coating method, the spray coating method, the kiss coating method, the reverse kiss coating method, the air knife coating method, the curtain coating method, the rod coating method or the like is preferred.

The laminate can also be made by preliminarily forming the electromagnetic wave-absorbing sheet by kneading the resin and the electromagnetic wave-absorbing material and extruding the resulting material, applying the composition for adhesive layer formation or a conventionally known adhesive onto one plane or both planes of the metal layer or the graphite layer being the outermost layer of the laminate, and when necessary preliminarily drying the resulting material, and then bringing the electromagnetic wave-absorbing sheet into contact with the applied plane, and when necessary applying pressure or heating. Moreover, the electromagnetic wave-absorbing sheet can also be thermally directly pressure-bonded onto one plane or both planes of the metal layer or the graphite layer being the outermost layer of the laminate. On the above occasion, a heat-resistant mold releasing film or paper is preferably used so as to avoid attachment of a fused electromagnetic wave-absorbing sheet onto an instrument. As the electromagnetic wave-absorbing sheet, a commercially available product may be directly used.

### EXAMPLES

The invention will be described in detail below using Examples. However, the invention is not limited to the content described in Examples below.

Materials used in Examples of the invention are as described below.

### Graphite Sheet

Graphite sheet (artificial graphite): SS-1500 (trade name) made by GrafTECH International Holdings Inc., thickness 25 micrometers (thermal conductivity in a direction of a sheet plane: 1,500 W/m·K).

### Metal Sheet

Electrolytic copper foil: made by Furukawa Electric Co., Ltd., 18 micrometers

Rolled copper foil: made by Nilaco Corporation, thickness 50 micrometers

Hard aluminum foil: made by SUACJ Foil Corporation, thickness 20 micrometers

### Polyvinyl Acetal Resin

“PVF-K”: polyvinyl formal resin, Vinylec K (trade name), made by JNC Corporation

Structure and so forth of the “PVF-K” are described in Table 1 below.

TABLE 1

| | Molecular | Consti- | Consti- | Consti- | Consti- |
|---|---|---|---|---|---|
| | weight | tutional | tutional | tutional | tutional |
| | (Mw) | unit A | unit B | unit C | unit D |
| | [—] | [mol %] | [mol %] | [mol %] | [mol %] |
| PVF-K | 45,000 | 75.7 | 11.5 | 12.9 | — |

### Thermally Conductive Pressure-Sensitive Adhesive Double Coated Tape

TR-5310F, made by Nitto Denko Corporation, thickness 0.100 millimeter

### Electromagnetic Wave-Absorbing Sheet

Noise suppression sheet 1 (soft magnetic material sheet) IRJ09 material, made by TDK Corporation, thickness 0.1 millimeter, with a 30 micrometer-thick double-sided tape, permeability (1 MHz) 180 (DigiKey Corporation part number 445-8699-ND).

Noise suppression sheet 2 (soft magnetic material sheet) IRJ09 material, made by TDK Corporation, thickness 0.1 millimeter, without a double-sided tape, permeability (1 MHz) 180 (Digi Key Corporation part number 445-8712-ND).

### Ferrite Powder

MnZn ferrite powder LD-M, made by JFE Chemical Corporation

### Polyester-Polyurethane Resin Dispersion Liquid

IMPRANIL DLP-R, made by Sumika Bayer Urethane Co., Ltd.

### Example 1

### Preparation of Laminate

In a 200 mL three-neck flask, 80 g of cyclopentanone was put, a stirring blade made of a fluorocarbon resin was set from an upper part, and the stirring blade was rotated with a motor. A speed of revolution was adjusted timely according to viscosity of a solution. Into the flask, 10 g of polyvinyl formal resin (PVF-K) was charged using a glass funnel. After rinsing off PVF-K adhered onto the funnel with 20 g of cyclopentanone, the funnel was removed and a glass stopper was placed thereon. The solution obtained was heated for 4 hours under stirring in a water bath set at 80° C. to completely dissolve PVF-K in cyclopentanone. The flask after stirring was removed from the water bath to obtain a composition for adhesive layer formation.

The composition for adhesive layer formation was applied onto copper foil having a size of 100 mm×100 mm and a thickness of 18 μm by using a spin coater (model 1H-D3, made by Mikasa Co., Ltd.), at 1,500 revolutions per minute to be 2 μm in a thickness of the adhesive layer obtained, and then the resulting material was preliminarily dried for 3 minutes on a hot plate set at 80° C. to obtain copper foil with an adhesive coating film. In addition, a copper foil adhesion plane was subjected to roughening treatment in order to improve adhesion performance, and measurement of a film thickness is difficult. Therefore, a concentration of the composition for adhesive layer formation and the speed of revolutions of the spin coater were determined in such a manner that a thickness of the adhesive layer on the copper sheet became substantially 2 μm by using a 0.5 mm-thick copper plate preliminarily subjected to mirror plane-polishing.

A 25 μm-thick graphite sheet (SS-1500) preliminarily cut into a size of 100 mm×100 mm was interposed between two sheets of the copper foil with the adhesive coating film with the adhesive coating film facing inward, and the resulting laminate was left to stand on a hot platen of a compact heating press (IMC-19EC type small heating hand press, made by Imoto Machinery Co., Ltd.). The adhesive coating film was deaerated by repeating pressurization and decompression several times while attention was paid on causing no slip of two sheets of copper foil and the graphite sheet, and then pressurized up to 6 MPa. Then, the hot plate was heated to 220° C. by using a heater, and temperature and pressure were held for 30 minutes. After elapse of 30 minutes, power supply to the heater was turned off while the pressure was held, and the film was naturally cooled to about 50° C. After cooling, the pressure was released to obtain laminate 1.

The laminate obtained and noise suppression sheet 1 made by TDK Corporation and cut into a size of 100×100 mm were laminated by using a pressure-sensitive adhesive attached to the noise suppression sheet while attention was paid on avoiding entry of air bubbles to obtain electromagnetic wave-absorbing and heat-dissipating sheet 1 (shown in FIG. 2).

With regard to an EMI test, a transmission attenuation power ratio (Rₜₚ) of a sample obtained by cutting the electromagnetic wave-absorbing and heat-dissipating sheet 1 into a size of 100 mm×50 mm was measured using E8361A Network Analyzer made by Agilent Technologies, Inc. and a measurement kit (specified in IEC Standard No.: IEC62333-1 and IEC62333-2) made by Keycom Corporation.

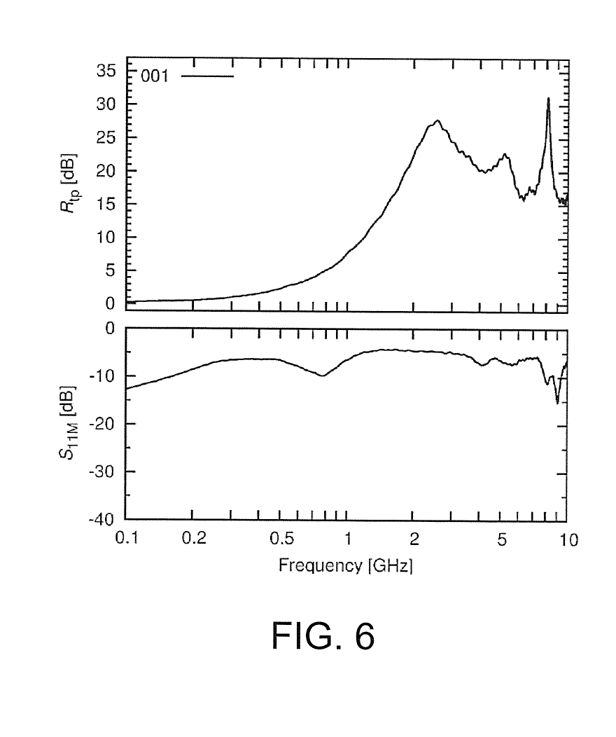

FIG. 6 shows the results of the EMI test on the electromagnetic wave-absorbing and heat-dissipating sheet obtained in Example 1.

### Comparative Example 1

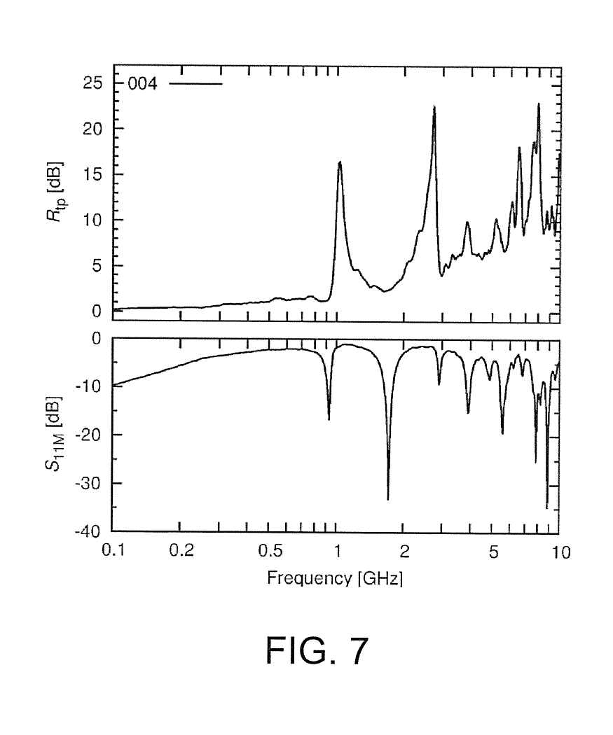

An EMI test was conducted by using, as comparative sample 1, only a copper-graphite laminate (laminate 1) before the noise suppression sheet was attached thereon in Example 1. FIG. 7 shows the results.

If Example 1 is compared with Comparative Example 1, noise of electromagnetic waves is effectively suppressed by an effect of a noise suppression layer on a sheet surface in Example 1. In comparison, when the surface remains to be metal as in Comparative Example 1, most of the electromagnetic waves are found to be reflected by the metal. Accordingly, the noise of the electromagnetic waves is found to be suppressible by using the electromagnetic wave-absorbing and heat-dissipating sheet of the invention.

### Comparative Example 2

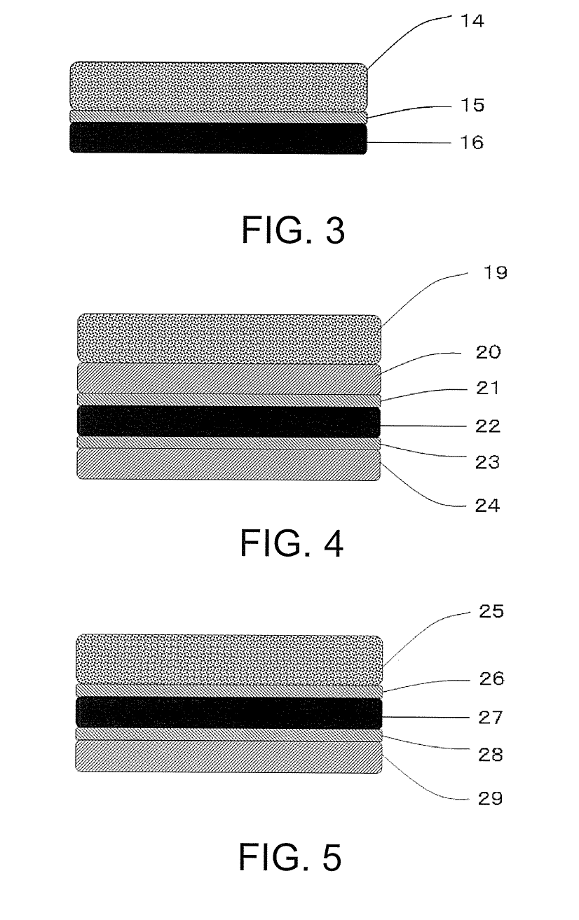

Comparative sample 2 (shown in FIG. 3) was obtained by laminating noise suppression sheet 1 made by TDK Corporation and cut into a size of 100×100 mm, and a 25 μm-thick graphite sheet (SS-1500) cut into a size of 100 mm×100 mm by using a pressure-sensitive adhesive sheet attached to a noise suppression sheet while attention was paid on avoiding entry of air bubbles.

### Comparative Example 3

Comparative sample 3 was obtained by laminating noise suppression sheet 1 made by TDK Corporation and cut into a size of 100×50 mm, and a 50 μm-thick graphite sheet (SS-1500) cut into a size of 100 mm×100 mm by using a pressure-sensitive adhesive sheet attached to a noise suppression sheet while attention was paid on avoiding entry of air bubbles.

### Evaluation of Heat-Dissipation Characteristics of Electromagnetic Wave-Absorbing and Heat-Dissipating Sheet

Heat dissipation experiments were conducted on electromagnetic wave-absorbing and heat-dissipating sheet 1 obtained in Example 1, comparative sample 1, comparative sample 2 and noise suppression sheet 2 made by TDK Corporation. Table 1 shows the results. In addition, a procedure of the heat dissipation experiment is as described below.

### Evaluation of Heat-Dissipation Characteristics

On one plane of a test specimen, a heat-resistant coating material (heat-resistant coating material One Touch, made by Okitsumo Inc.) was sprayed and dried to be about 20 μm in a thickness of the coating film. In a central part on a side of a plane the resulting heat-dissipating member on which no heat-resistant coating material was coated, a T0220 package transistor (2SD2013; made by Toshiba Corporation) was attached using a double-sided tape (TR-5310F, made by Nitto Denko Corporation) A K thermocouple (ST-50, made by RKC Instrument Inc.) is attached on a rear plane of a plane of the transistor on which the heat-dissipating member was bonded, and temperature of the transistor on a plane on a side opposite to the plane on which the heat-dissipating member was bonded can be recorded by using a temperature data logger (GL220 made by Graphtec Corporation). The transistor on which the thermocouple was attached was left to stand in a center of a constant temperature bath set at 40° C., the temperature of the transistor was confirmed to become constant at 40° C., and then 1.25 V was applied to the transistor by using a stabilized direct current power supply, and a temperature change on a surface was measured. The temperature of the transistor after 1,800 seconds from applying the voltage was measured. Table 2 summarizes measurement results.

The transistor generates a predetermined amount of heat if same wattage is applied, and therefore the temperature decreases as a heat-dissipating effect of the heat-dissipating member attached is higher. More specifically, the heat-dissipating member in which the temperature of the transistor decreases can be reasonably referred to have a higher heat-dissipating effect.

TABLE 2

| | Electromagnetic | | | Only noise |
|---|---|---|---|---|
| | wave-absorbing | | | suppression |
| | and heat- | Compar- | Compar- | sheet 2 |
| | dissipating | ative | ative | made by TDK |
| | sheet 1 | sample 2 | sample 3 | Corporation |
| Temperature | 67.8 | 70.5 | 72.5 | 88.3 |
| of transistor | | | | |
| after 1,800 | | | | |
| seconds | | | | |
| (° C.) | | | | |

As is known from the results in Table 2 and the EMI tests, both a high heat-dissipation capability and electromagnetic wave noise suppression capability are known to be compatible by using the metal layer electromagnetic wave-absorbing and heat-dissipating sheet of the invention.

### Example 2

An electromagnetic wave-absorbing composition coating material 1 was prepared by mixing 250 (g) of MnZn ferrite powder (LD-M) made by JFE Chemical Corporation to 100 (g) of IMPRANIL DLP-R made by Sumika Bayer Urethane Co., Ltd. Laminate 2 was obtained using two sheets of hard aluminum foil (0.02 mm thick) in place of copper foil, and graphite SS-1500 (25 μm) in a manner similar to Example 1. Electromagnetic wave-absorbing and heat-dissipating sheet 2 (shown in FIG. 4) was prepared by applying the electromagnetic wave-absorbing composition coating material onto laminate 2 by a spin coater, and heating and drying the resulting material in an oven set at 80° C. In addition, application and heating were repeated in several batched to be 100 μm in a thickness of the electromagnetic wave-absorbing layer.

### Example 3

Electromagnetic wave-absorbing composition coating material 2 was prepared by mixing 15.5 (g) of MnZn ferrite powder (LD-M) made by JFE Chemical Corporation to 100 (g) of the composition for adhesive layer formation used in Example 1. Laminate 2 was obtained using two sheets of hard aluminum foil (0.02 mm thick) and graphite SS-1500 (25 μm) in a manner similar to Example 2. Electromagnetic wave-absorbing and heat-dissipating sheet 2 was prepared by applying the electromagnetic wave-absorbing composition coating material onto laminate 2, and heating and drying the resulting material in an oven set at 80° C. Application and heating were repeated in several batches to be 100 μm in a thickness of the electromagnetic wave-absorbing layer.

### Example 4

Electromagnetic wave-absorbing composition coating material 3 was prepared by mixing 250 (g) of NiZn ferrite powder (KNI-106) made by JFE Chemical Corporation to 100 (g) of IMPRANIL DLP-R made by Sumika Bayer Urethane Co., Ltd. Electromagnetic wave-absorbing and heat-dissipating sheet 3 (shown in FIG. 4) was prepared by applying the electromagnetic wave-absorbing composition coating material 3 onto laminate 2 by a spin coater, and heating and drying the resulting material in an oven set at 80° C. Application and heating were repeated in several batches to be 100 μm in a thickness of the electromagnetic wave-absorbing layer.

### Comparison Samples 4 and 5

Comparative examples 4 and 5 were prepared by applying the electromagnetic wave-absorbing composition coating material onto graphite SS-1500 (25 μm), and heating and drying the resulting material in an oven set at 80° C. in a manner similar to Examples 2 and 3. Application and heating were repeated in several batches to be 100 μm in a thickness of the electromagnetic wave-absorbing layer.

### Example 5

Measurement of heat dissipation was performed on the samples prepared in Examples 2 and 3 and comparative samples 4 and 5 in a manner similar to Example 1. Table 3 shows the results.

TABLE 3
Temperature of transistor after 1,800 seconds

| | Electromagnetic | Electromagnetic | Electromagnetic |
|---|---|---|---|
| | wave-absorbing | wave-absorbing | wave-absorbing |
| | composition | composition | composition |
| Base | coating | coating | coating |
| material | material 1 | material 2 | material 3 |
| Laminate 2 | 67.5° C. | 68.8° C. | 67.1° C. |
| | (Example 2) | (Example 3) | (Example 4) |
| Graphite | Inapplicable by | 71.1° C. | Inapplicable by |
| sheet | repellence | (comparative | repellence |
| SS-1500 | (Comparative | sample 5) | (Comparative |
| | sample 4) | | sample 5) |

Although an already formed electromagnetic wave-suppressing sheet was used in Example 1, an objective electromagnetic wave-absorbing and heat-dissipating sheet is found to be obtainable also by applying and solidifying the electromagnetic wave-absorbing composition coating material to the metal and the graphite sheet, as in Example 2 or Example 3. Moreover, a surface of graphite generally has very poor adhesion performance with the adhesive or the coating material, and repels the coating material or causes easy peeling of the coating film. However, a problem of the adhesion performance can be solved by (1) improvement in the adhesion performance with a variety of resins by applying the electromagnetic wave-absorbing composition coating material onto the sheet preliminarily laminated with the metal layer as in the invention, or (2) by forming a film of the electromagnetic wave-absorbing composition coating material by using, as a binder or primer, the polyvinyl acetal resin used in the adhesive layer of the invention (FIG. 5).

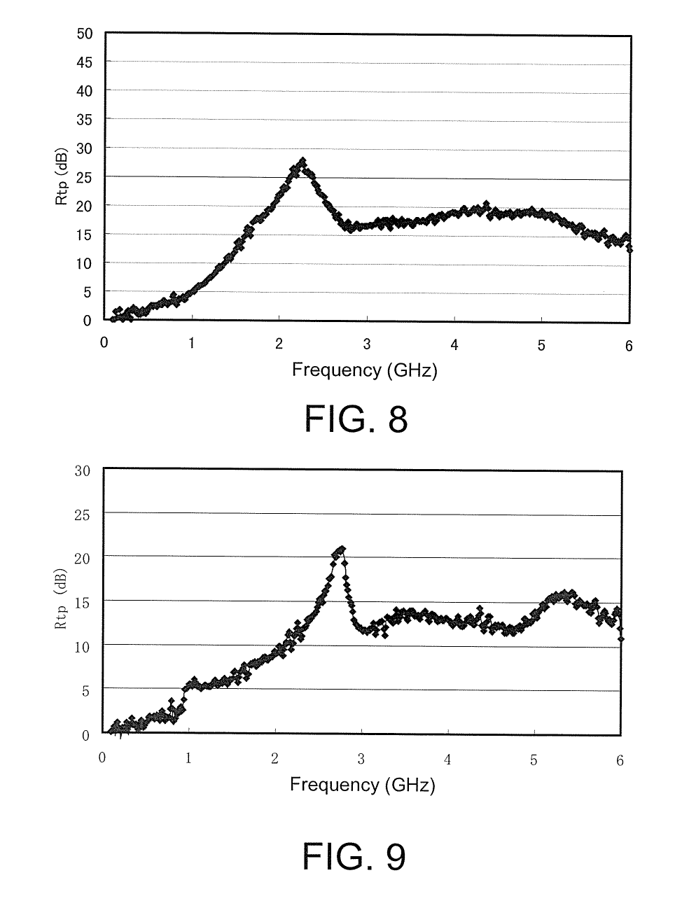

An EMI test was performed also on the samples in Example 2 and Example 3 by using the network analyzer in a manner similar to Example 1. FIG. 8 and FIG. 9 show the results, respectively.

From the results of the heat dissipation test and the results of the EMI test, the electromagnetic wave-absorbing and heat-dissipating sheet that has high performance and is easy to handle is found to be obtained.

### REFERENCE SIGNS LIST

FIG. 1
1: Laminate 1
2: Copper foil
3: Adhesive layer
4: Graphite layer
5: Adhesive layer
6: Copper foil

FIG. 2
7: Noise suppression sheet
8: Commercially available pressure-sensitive adhesive layer for fixing noise suppression sheet
9: Metal foil
10: Adhesive layer
11: Graphite layer
12: Adhesive layer
13: Metal foil.

FIG. 3
14: Noise suppression sheet
15: Commercially available pressure-sensitive adhesive layer for fixing noise suppression sheet
16: Graphite layer

FIG. 4
19: Electromagnetic wave-absorbing composition coating film
20: Metal foil
21: Adhesive layer
22: Graphite layer
23: Adhesive layer
24: Metal foil

FIG. 5
25: Electromagnetic wave-absorbing composition coating film
26: Adhesive layer (Primer layer)
27: Graphite layer
28: Adhesive layer
29: Metal foil

1. An electromagnetic wave-absorbing and heat-dissipating sheet, comprising at least one electromagnetic wave-absorbing layer including an electromagnetic wave-absorbing material, at least one graphite layer formed of a graphite sheet, and at least one metal layer, wherein the graphite layer and other layers are adhered using an adhesive layer composed of a composition containing a polyvinyl acetal resin.

2. The electromagnetic wave-absorbing and heat-dissipating sheet according to claim 1, wherein the electromagnetic wave-absorbing layer is a mixture of the electromagnetic wave-absorbing material and the resin.

3. The electromagnetic wave-absorbing and heat-dissipating sheet according to claim 1, wherein the electromagnetic wave-absorbing material is a soft magnetic material or ferrite.

4. The electromagnetic wave-absorbing and heat-dissipating sheet according to claim 1, wherein the electromagnetic wave absorbing material is any one of kind selected from the group of Permalloy, Sendust, silicon steel, alloy Alperm, Permendur and electromagnetic stainless steel, or a mixture of two or more kinds thereof.

5. The electromagnetic wave-absorbing and heat-dissipating sheet according to claim 1, wherein the metal layer includes copper, aluminum, magnesium or titanium.

6. The electromagnetic wave-absorbing and heat-dissipating sheet according to claim 1, wherein the polyvinyl acetal resin forming the adhesive layer includes the following constitutional units A, B and C: 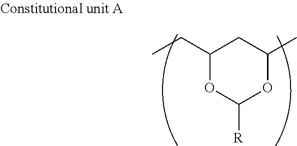
wherein, in constitutional unit A, R is independently hydrogen or alkyl:

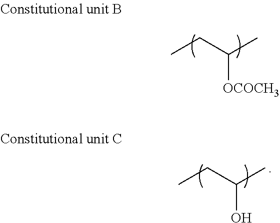

7. The electromagnetic wave-absorbing and heat-dissipating sheet according to claim 6, wherein the polyvinyl acetal resin further includes the following constitutional unit D: 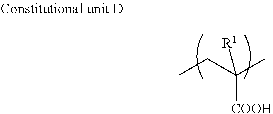
wherein, in constitutional unit D, R¹ is independently hydrogen or alkyl having 1 to 5 carbons.

8. The electromagnetic wave-absorbing and heat-dissipating sheet according to claim 1, wherein thermal conductivity of the graphite layer in a plane direction is 300 to 2,000 W/m·K.

9. The electromagnetic wave-absorbing and heat-dissipating sheet according to claim 1, wherein a thickness of the adhesive layer is 5 micrometers or less.

10. An electronic equipment, wherein the electromagnetic wave-absorbing and heat-dissipating sheet according to claim 1 is thermally brought into contact with a heating unit.
